(19) United States
(12) Patent Application Publication
(10) Pub. No.: US 2012/0119179 A1
(43) Pub. Date: May 17, 2012

(54) MEMORY DEVICE AND METHOD FOR MANUFACTURING THE SAME

(75) Inventors: Shinichi Nakao, Kanagawa-ken (JP); Kei Watanabe, Tokyo (JP); Kazuhiko Yamamoto, Kanagawa-ken (JP); Ichiro Mizushima, Kanagawa-ken (JP); Yoshio Ozawa, Kanagawa-ken (JP)

(73) Assignee: Kabushiki Kaisha Toshiba, Tokyo (JP)

(21) Appl. No.: 13/354,380

(22) Filed: Jan. 20, 2012

Related U.S. Application Data
(63) Continuation-in-part of application No. 13/052,354, filed on Mar. 21, 2011.

(30) Foreign Application Priority Data
Nov. 5, 2010 (JP) 2010-248375
Sep. 21, 2011 (JP) 2011-206467

(51) Int. Cl. H01L 47/00; H01L 21/02; B82Y 99/00; B82Y 40/00

(52) U.S. Cl. 257/2; 438/382; 977/742; 977/842; 257/E47.001; 257/E21.004

(57) ABSTRACT

According to one embodiment, a memory device includes a nanomaterial aggregate layer of a plurality of fine conductors aggregating via gaps and an insulating material disposed in the gaps.

### CROSS-REFERENCE TO RELATED APPLICATIONS

This is a Continuation-in-Part application of application Ser. No. 13/052,354, filed on Mar. 21, 2011; the entire contents of which are incorporated herein by reference.

This application is based upon and claims the benefit of priority from the prior Japanese Patent Application No. 2010-248375 filed on Nov. 5, 2010; No. 2011-206467 filed on Sep. 21, 2011; the entire contents of which are incorporated herein by reference.

### FIELD

Embodiments described herein relate generally to a memory device and a method for manufacturing the same.

### BACKGROUND

In recent years, there has been found a phenomenon in which, when applying a voltage to a specific material of metal oxide, the material gives two types of states, a low-resistance state and a high-resistance state, depending on the magnitude of resistivity before applying the voltage and on the magnitude of applied voltage. Thus, new non-volatile memory devices utilizing the phenomenon are gathering attention. The non-volatile memory device is referred to as the “resistance random access memory (ReRAM)”. Regarding the real device structure of ReRAM, there is a proposal of three-dimensional cross point structure in which a memory cell is disposed at a crossing point of word line (WL) and bit line (BL) from the viewpoint of attaining high integration. Further, for commercializing ReRAM, the improvement in the reliability is required.

### BRIEF DESCRIPTION OF THE DRAWINGS

FIG. 1 is a perspective view illustrating a memory device according to a first embodiment;

FIG. 2 is a schematic cross-sectional view illustrating a pillar of the memory device according to the first embodiment;

FIG. 3 is a flow chart illustrating a method of forming pillar in the first embodiment;

FIGS. 4A and 4B, and FIGS. 5A and 5B are process cross-sectional views illustrating a method for manufacturing the memory device according to the first embodiment;

FIG. 6 is a schematic cross-sectional view illustrating the pillar of a memory device according to a comparative example;

FIG. 7 is a graph illustrating switching characteristics of memory device according to an example;

FIG. 8 is a graph illustrating the effect of an insulating material on an adhesive strength of a nanomaterial aggregate layer;

FIG. 9 is a flow chart illustrating a method of forming pillar in a second embodiment;

FIG. 10 is a flow chart illustrating a method of forming pillar in a third embodiment;

FIG. 11 is a flow chart illustrating a method of forming pillar in a fourth embodiment;

FIG. 12 is a schematic cross-sectional view illustrating a pillar of a memory device according to the fourth embodiment;

FIG. 13 is a flow chart illustrating a method of forming pillar in a fifth embodiment;

FIGS. 14A and 14B, and FIGS. 15A and 15B are process cross-sectional views illustrating a method for manufacturing a memory device according to a sixth embodiment;

FIGS. 16A and 16B are process views illustrating the method for manufacturing the memory device according to the sixth embodiment, FIG. 16A illustrates an upper process view and FIG. 16B illustrates a cross-sectional process view;

FIGS. 17A and 17B are cross-sectional process views illustrating a method for manufacturing a memory device according to a comparative example;

FIG. 18 is a cross-sectional process view illustrating the method for manufacturing the memory device according to the sixth embodiment;

FIG. 19 is an upper schematic view illustrating a variation of the memory device according to the sixth embodiment;

FIG. 20 is a flow chart illustrating a method of forming pillar in a seventh embodiment; and

FIG. 21 is a schematic cross-sectional view illustrating the pillar of the memory device according to the seventh embodiment.

### DETAILED DESCRIPTION

In general, according to one embodiment, a memory device includes a nanomaterial aggregate layer of a plurality of fine conductors aggregating via gaps and an insulating material disposed in the gaps.

Various embodiments will be described hereinafter with reference to the accompanying drawings.

The description will begin with a first embodiment.

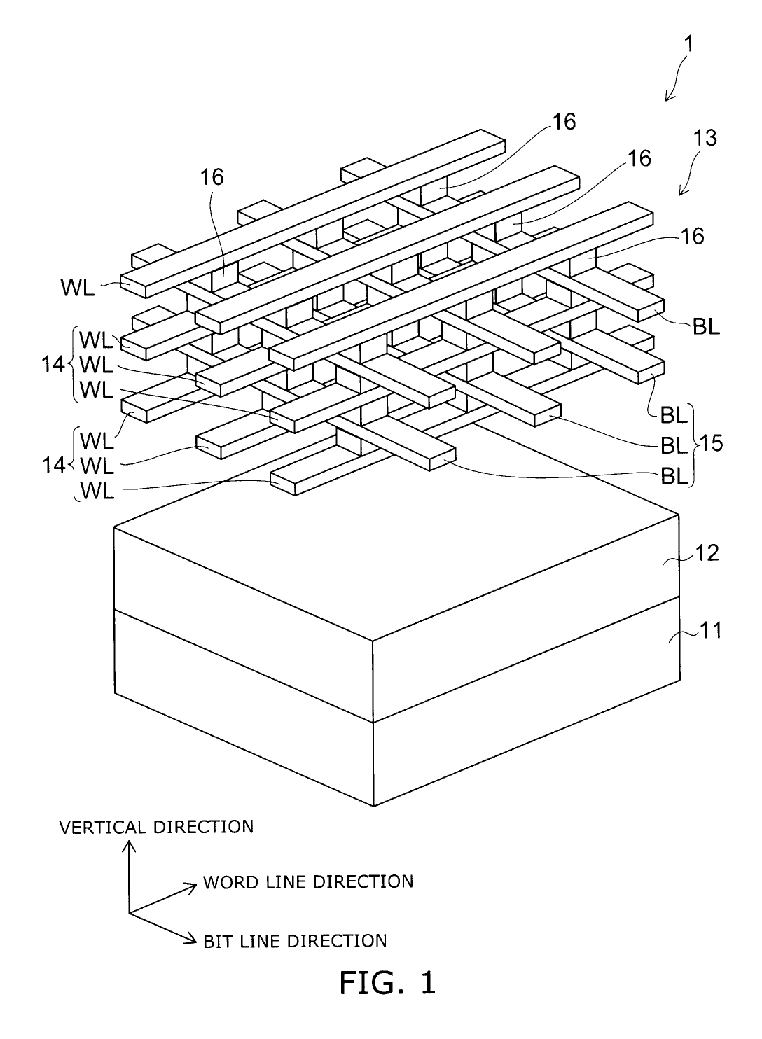

FIG. 1 is a perspective view illustrating a memory device according to the embodiment.

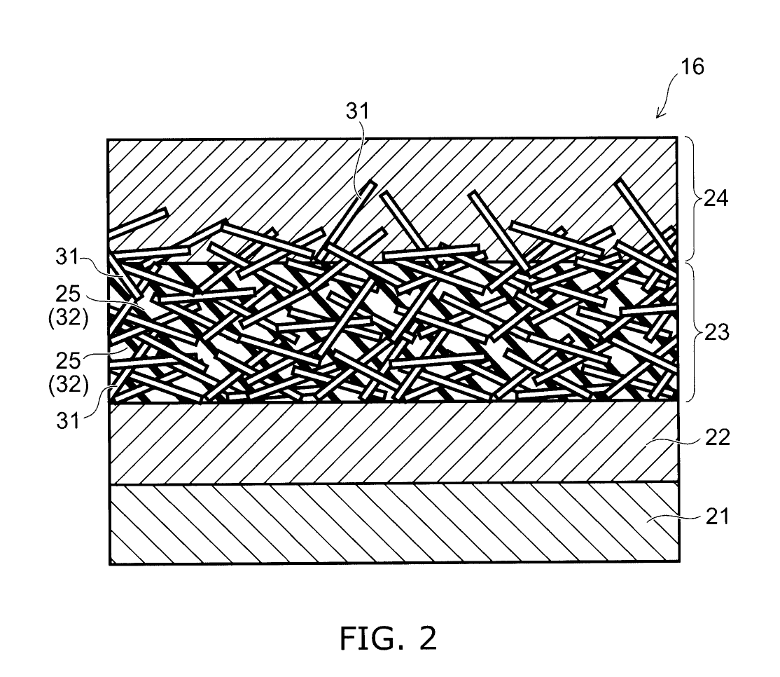

FIG. 2 is a schematic cross-sectional view illustrating a pillar of the memory device according to the embodiment.

The memory device according to the embodiment is a non-volatile memory device, and more specifically, a ReRAM using fine conductors.

As illustrated in FIG. 1, a memory device 1 according to the embodiment has a silicon substrate 11. A drive circuit (not shown) of the memory device 1 is formed in upper layer part and on upper surface of the silicon substrate 11. An interlayer insulating film 12 made of, for example, silicon oxide is positioned on the silicon substrate 11 so as to bury the drive circuit therein. A memory cell part 13 is positioned on the interlayer insulating film 12.

In the memory cell part 13, there are stacked alternately a word line interconnect layer 14 containing pluralities of word lines WL extending in one direction parallel to the upper surface of the silicon substrate 11 (hereinafter referred to as the “word line direction”), and a bit line interconnect layer 15 containing pluralities of bit lines BL extending in parallel to the upper surface of the silicon substrate 11 and in a direction to intersect with the word line direction, for example orthogonal to the word line direction, (hereinafter referred to as the “bit line direction”), via an insulating layer. Word lines are not in contact with each other, bit lines are not in contact with each other, and word line WL and bit line BL are not in contact with each other.

At the most proximal point between each word line WL and each bit line BL, there is positioned a pillar 16 extending in a vertical direction relative to the upper surface of the silicon substrate 11 (hereinafter referred to as the “vertical direction”). The pillar 16 is formed between the word line WL and the bit line BL. A single pillar 16 structures a single memory cell. That is, the non-volatile memory device 1 is a cross point type device in which a memory cell is positioned at every most proximal point between the word line WL and the bit line BL. The space among the word line WL, the bit line BL, and the pillar 16 is filled with an interlayer insulating film (not shown).

The structure of the pillar 16 will be described below referring to FIG. 2.

As illustrated in FIG. 2, in each pillar 16, there are stacked, in order from bottom to top, a silicon diode layer 21, a lower electrode layer 22, a nanomaterial aggregate layer 23, and an upper electrode layer 24. Furthermore, as described later, an insulating material 25 is buried in the nanomaterial aggregate layer 23. The silicon diode layer 21 is in contact with, for example, the word line WL (refer to FIG. 1), and the upper electrode layer 24 is in contact with, for example, the bit line BL (refer to FIG. 1). Moreover, the lower electrode layer 22 is in contact with the lower surface of the nanomaterial aggregate layer 23, and the upper electrode layer 24 is in contact with the upper surface of the nanomaterial aggregate layer 23. Meanwhile, in between the word line WL and the silicon diode layer 21, a barrier metal layer may be formed in order to prevent diffusion and improve adhesion. In addition, on side surface of the pillar 16, a side wall (not shown) made of, for example, silicon is formed.

The silicon diode layer 21 is made of, for example, polysilicon, and is structured by stacking, in order from the word line WL side, an n-type layer having n⁺-conduction type, an i-type layer made of an intrinsic semiconductor, and a p-type layer having p⁺-conduction type. With the structure, the silicon diode layer 21 functions as a selection element layer which allows current to flow only when a potential higher than the potential applied to the word line WL is applied to the bit line BL, and which does not allow the current to flow in reverse direction.

The lower electrode layer 22 is formed by a conductive material such as tungsten (W), titanium nitride (TiN), tungsten nitride (WN), tantalum nitride (TaN), and titanium silicide (TiSi).

The nanomaterial aggregate layer 23 is a layer in which carbon nanotubes (CNT) 31 as fine conductors loosely aggregate each other through gaps 32 therebetween. Each CNT 31 is in a cylindrical shape, having a length of, for example, about 500 nm. The direction in which most of the CNTs 31 extends is more close to a direction parallel to the lower surface of the nanomaterial aggregate layer 23 rather than to a vertical direction to the lower surface thereof (vertical direction). Furthermore, there exists no CNT 31 which contacts with both the lower electrode layer 22 and the upper electrode layer 24. Moreover, the aspect ratio of the nanomaterial aggregate layer 23 is 1 or less. That is, the thickness of the nanomaterial aggregate layer 23 is not more than the width thereof.

Further, in the gap 32, the insulating material 25 is placed. Preferably, the insulating material 25 is a material which, for example, has relatively small molecular weight, is hydrophobic, has resistance to ammonia, secures adhesion by polycondensation reaction and the like, and does not damage the CNT when filling the gap. Applicable insulating material 25 can include, for example, spin-on dielectric (SOD) containing silicon (Si), oxygen (O), carbon (C), and hydrogen (H); such as methylsilsesquioxane (MSQ). The gap 32 is filled with that type of insulating material 25 substantially free from void therein.

The upper electrode layer 24 is made of a conductive material similar to that of the lower electrode layer 22. At lower part of the upper electrode layer 24, a portion of the CNT 31 structuring the nanomaterial aggregate layer 23 is buried therein. The lower surface of the upper electrode layer 24 is in contact with the insulating material 25.

In each pillar 16, the silicon diode layer 21 functions as the selection element layer to switch between flowing and not flowing current through the pillar 16. The nanomaterial aggregate layer 23 changes between “low-resistance state” and “high-resistance state” depending on the applied voltage or current, and thus functions as the memory layer for storing binary data. Further, each pillar 16 functions as the memory cell because of having both the selection element layer and the memory layer. In the nano-material aggregate layer 23, it is preferable that no CNT 31 contacting with both the lower electrode layer 22 and the upper electrode layer 24 exists. With the structure, the resistivity of the nano-material aggregate layer 23 in “high-resistance state” becomes high, and thus the operation margin of the memory cell can be satisfactorily assured.

Next will be the description of a method for manufacturing the non-volatile memory device according to the embodiment.

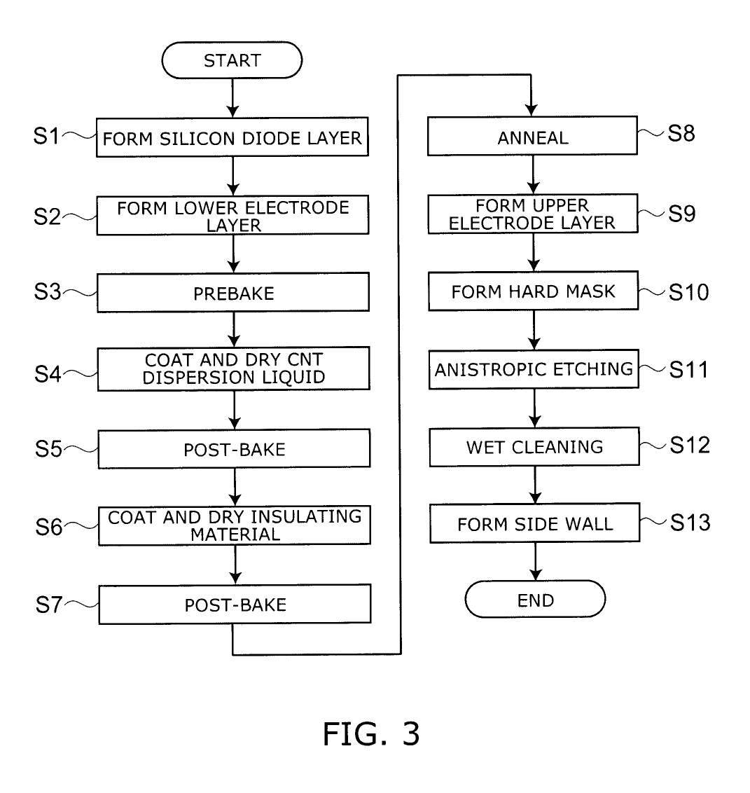

FIG. 3 is a flow chart illustrating a method of forming pillar, in the method for manufacturing the memory device according to the embodiment.

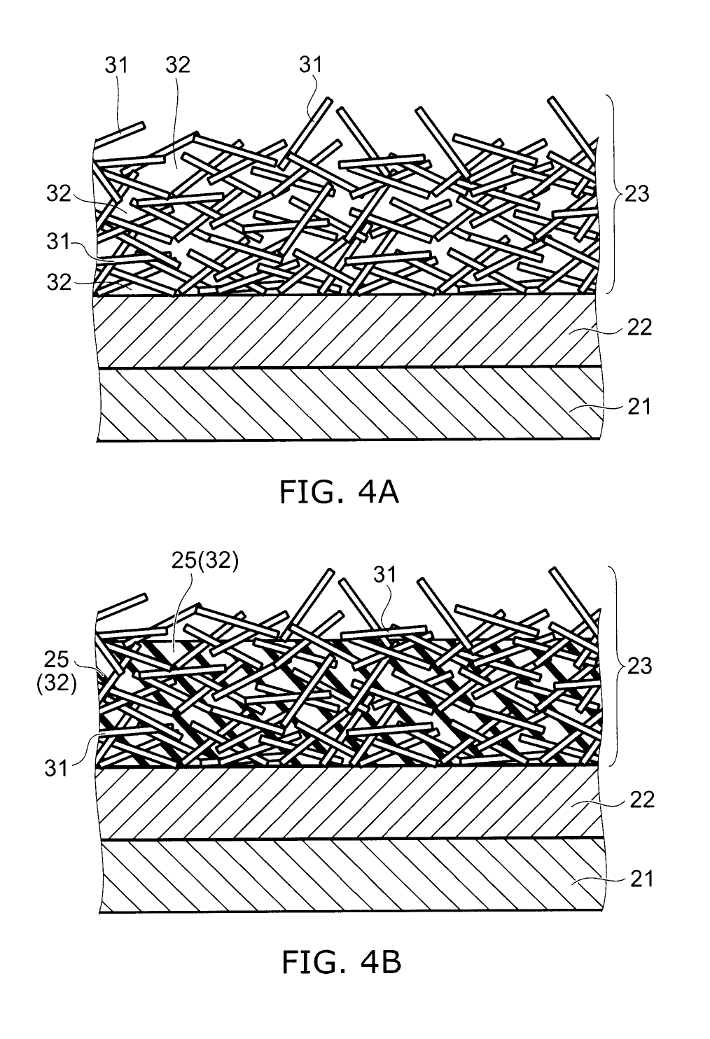

FIGS. 4A and 4B, and FIGS. 5A and 5B are process cross sections illustrating the method for manufacturing the memory device according to the embodiment.

As illustrated in FIG. 1, the drive circuit for driving the memory cell part 13 is formed on upper surface of the silicon substrate 11. Next, the interlayer insulating film 12 is formed on the silicon substrate 11. Then, a contact (not shown) reaching the drive circuit is formed in the interlayer insulating film 12. After that, tungsten is buried in the upper layer part of the interlayer insulating film 12 by using, for example, Damascene technique, and thus pluralities of word lines WL are formed in parallel each other so as to extend in the word line direction. These word lines WL form the word line interconnect layer 14.

The method of forming the pillar 16 will be described below referring to FIGS. 2 to 5B.

First, as illustrated in FIG. 2 and the Step 51 in FIG. 3, the silicon diode layer 21 is formed by depositing amorphous silicon on the word line interconnect layer 14 by using, for example, chemical vapor deposition (CVD) method. In this operation, the respective impurities are doped while the amorphous silicon is deposited, to thereby successively form the n-type layer, the i-type layer, and the p-type layer. Meanwhile, there may be formed a barrier metal layer (not shown) made of, for example, titanium nitride (TiN) between the word line interconnect layer 14 and the silicon diode layer 21, as necessary.

Next, as illustrated in FIG. 2 and the Step S2 in FIG. 3, the lower electrode layer 22 is formed by depositing a conductive material such as tungsten or titanium nitride on the silicon diode layer 21 by using, for example, physical vapor deposition (PVD) method.

Then, a structure body in which the above-described respective layers are formed on the silicon substrate 11 (hereinafter referred to simply as the “substrate”), is charged into a coater (not shown). As shown by the Step S3 in FIG. 3, prebaking (heat treatment before coating) is performed by a hot plate. In this operation, for example, the atmosphere is a nitrogen atmosphere, the heating temperature is in a range of 200° C. to 300° C., and the heating time is 5 minutes. After that, the temperature of the substrate is lowered to room temperature.

Next, as shown by the Step S4 in FIG. 3 and illustrated in FIG. 4A, a dispersion liquid in which CNT 31 is dispersed is coated on the substrate by using the spin-coating method. That is, while rotating the substrate at a speed of, for example, about 1000 to about 2000 rpm, a dispersion liquid having, for example, a volume of about 1 cm³ is added dropwise onto the substrate, and thus the dispersion liquid is coated and spread on the substrate. After that, the coated dispersion liquid is dried. The coating and drying cycle is repeated necessary times to thereby form the nanomaterial aggregate layer 23. In the nanomaterial aggregate layer 23, pluralities of CNTs 31 aggregate, and the gap 32 is formed between CNTs 31. Furthermore, during the process of drying the dispersion liquid to decrease in the thickness thereof, the direction in which the CNT 31 extends becomes close to a horizontal direction, that is, to a direction parallel to the plane created by the word line direction and the bit line direction. Moreover, since the coating and drying cycle of the dispersion liquid is repeated pluralities of times, there exists no CNT 31 penetrating entire nanomaterial aggregate layer 23 in the thickness direction thereof.

Next, as shown by the Step S5 in FIG. 3, post-baking (heat treatment after coating) is performed by the hot plate of the coater. In this operation, for example, the atmosphere is a nitrogen atmosphere, the heating temperature is in a range of 200° C. to 300° C., and the heating time is 5 minutes. After that, the temperature of the substrate is lowered to room temperature.

Then, as shown by the Step S6 in FIG. 3 and illustrated in FIG. 4B, a solution containing the insulating material 25 as the solute, for example an MSQ solution, is coated on the substrate by using the spin-coating method. The molecular weight of the MSQ in the MSQ solution is adjusted to about 2000. Specifically, about 1 cm³ volume, for example, of a solution of the insulating material is added dropwise onto the substrate while rotating the substrate at a speed of, for example, about 1000 to about 2000 rpm, and thus the solution of insulating material is coated and spread on the substrate. After that, the coated solution is dried. As a result, the insulating material 25 is deposited in layers to form a deposited layer. At this time, the thickness of the deposited layer of the insulating material 25 after drying is adjusted not to exceed the thickness of the nanomaterial aggregate layer 23. That is, the insulating material 25 is filled in the gap 32 only at the lower part of the nanomaterial aggregate layer 23. In contrast, at the upper part of the nanomaterial aggregate layer 23, the insulating material 25 is not buried in the gap 32, and thus the CNT 21 is left exposed thereat. As a result, a part of the CNT 31 is protruded from the upper surface of the deposited layer made of the insulating material 25.

Then, as shown by the Step S7 in FIG. 3, post-baking (heat treatment after coating) is performed using the hot plate of the coater. In this operation, for example, the atmosphere is air, and the heating temperature is in a range from 100° C. to 200° C. After that, the temperature of the substrate is decreased to room temperature, and then the substrate is taken out from the coater.

Next, as shown by the Step S8 in FIG. 3, the substrate is charged into a vertical furnace to perform annealing (heat treatment). The annealing treatment is a heat treatment at higher temperature and for longer period than those of post-baking treatment shown by the Steps S5 and S7 in FIG. 3. For example, in the annealing treatment shown by the Step S8, the atmosphere is a nitrogen atmosphere, the heating temperature is in a range from 500° C. to 600° C., and the heating time is 1 hour. By the operation, cross-linking reaction occurs between CNTs 31 to join CNTs 31 loosely each other. In addition, in the insulating material 25, an OH group dehydration-condensation reaction occurs between MSQ molecules, and thus the cross-linking reaction takes place. After that, the substrate is cooled to room temperature, and the substrate is taken out from the vertical furnace.

Then, as shown by the Step S9 in FIG. 3 and illustrated in FIG. 5A, the substrate is charged to, for example, a PVD unit to deposit a conductive material such as tungsten and titanium nitride from the upper part of the nanomaterial aggregate layer using the PVD method. At this time, the conductive material enters into the gap 32 to deposit on the deposited layer made of the insulating material 25, and thus covers the portion of exposed CNT 31. As a result, the upper electrode layer 24 is formed while the CNT 31 is buried in lower part of the upper electrode layer 24. In this way, the portion of CNTs with buried insulating material 25 structures the nanomaterial aggregate layer 23, while the portion thereof with buried conductive material becomes a part of the upper electrode layer 24.

Next, as shown by the Step S10 in FIG. 3, a hard mask (not shown) made of for example silicon oxide is formed on the upper electrode layer 24. Then, a resist film (not shown) is formed on the hard mask, followed by performing patterning using the lithography to leave the resist film on a domain for forming the pillar 16. After that, by using the patterned resist film as the mask, there is performed anisotropic etching such as reactive ion etching (RIE) to perform patterning of the hard mask.

Then, as shown by the Step S11 in FIG. 3 and illustrated in FIG. 5B, the patterned hard mask is used as the mask to perform anisotropic etching such as RIE. By the etching, there are selectively removed the upper electrode layer 24, the nanomaterial aggregate layer 23, the lower electrode layer 22, and the silicon diode layer 21, and thus the pillar 16 is formed.

Next, as shown by the Step S12 in FIG. 3, wet-washing is performed using, for example, hydrofluoric acid-based chemicals such as diluted hydrofluoric acid (DHF) and buffered hydrofluoric acid (BHF) to remove byproducts (not shown) adhered onto the side surface of the pillar 16.

Then, as shown by the Step S13 in FIG. 3, silicon nitride is deposited by the CVD method using for example ammonia gas (NH₃) as the raw material to form the side wall (not shown) on the side surface of the pillar 16. After that, an insulating material such as silicon oxide is deposited to bury the space between pillars 16, and thus the interlayer insulating film (not shown) is formed. Then, chemical mechanical polishing (CMP) is applied using the upper electrode layer 24 as the stopper, and thus the upper surface of the interlayer insulating film is flattened.

Next, as illustrated in FIG. 1, pluralities of bit lines BL are formed on the pillar 16 and on the interlayer insulating film, and thus the bit line interconnect layer 15 is formed. Then, with a similar method to the above, there are stacked the silicon diode layer 21, the lower electrode layer 22, the nanomaterial aggregate layer 23, and the upper electrode layer 24, in this order, followed by performing patterning to form the pillar 16. After that, the pillar 16 is washed, the side wall is formed, and the gap is filled with the interlayer insulating film. In this way, the pillar 16 is formed on the bit line BL. When forming the pillar 16, the stacking order of the n-type layer, the i-type layer, and the p-type layer in the silicon diode layer 21 is reversed with respect to the pillar 16 formed on the word line WL. After that, a similar procedure is carried out repeatedly to form the word line interconnect layer 14, the pluralities of pillars 16, the bit line interconnect layer 15, and the pluralities of pillars 16. As a result, the memory device 1 according to the embodiment is manufactured.

Next, a description will be given of the effect of the embodiment.

According to the embodiment, the insulating material 25 is positioned in the gap 32 of the nanomaterial aggregate layer 23. By the structure, the mechanical strength of the nanomaterial aggregate layer 23 is increased. As a result, collapse of the pillar 16 at the nanomaterial aggregate layer 23 is prevented, and fracture at the nanomaterial aggregate layer as fracturing section is prevented. Consequently, the reliability of the memory device 1 is increased.

According to the embodiment, in the Step S6 shown in FIG. 3 and in the process illustrated in FIG. 4B, the insulating material 25 is filled in the gap 32 formed at lower part of the nanomaterial aggregate layer 23, and thus a deposited layer made of the insulating material 25 is formed. As a result, when forming the upper electrode layer 24 by depositing the conductive material, in the process shown by the Step S9 in FIG. 3 and illustrated in FIG. 5A, the entering of the conductive material into lower part I of the nanomaterial aggregate layer 23 can be regulated. Consequently, since the lower surface of the upper electrode layer 24 is determined by the upper surface of the deposited layer of the insulating material 25, the lower surface of the upper electrode layer 24 becomes flat. As a result, the thickness of the nanomaterial aggregate layer 23 becomes uniform, and the characteristics as the memory layer also become homogeneous. Thus, the reliability of the memory device 1 increases.

Since the mechanical strength of the nanomaterial aggregate layer 23 increases because of the presence of the insulating material 25, in the process shown by the Step S11 in FIG. 3 and illustrated in FIG. 5B, collapse of the pillar 16 can be prevented when forming the pillar 16 by using RIE. Furthermore, when performing RIE, since the insulating material 25 is buried, etching is not performed to the upper surface of the lower electrode layer 22 via the gap 32. As a result, the shape stability of the lower electrode layer 22 improves. In addition, when forming the side wall in the process of Step S13 in FIG. 3, the presence of the insulating material 25 can prevent the material of the side wall from entering from the side surface of the nanomaterial aggregate layer 23 thereinto. For the above reasons, the reliability of the memory device 1 can be improved.

Furthermore, according to the embodiment, the insulating material 25 is deposited by the coating method, and thus the burying ability of the insulating material 25 is improved, and the insulating material 25 can reliably reach the lower part of the nanomaterial aggregate layer 23. Since the coating method has high controllability of film thickness, the insulating material 25 can be buried only in the lower part of the nanomaterial aggregate layer 23. In addition, the coating method does not damage the CNT 31.

In contrast, if the insulating material 25 is deposited by the PVD method, the PVD method has poor burying ability so that the reliably causing the insulating material 25 to reach the lower part of the nanomaterial aggregate layer 23 becomes difficult, and also the control of deposition thickness of the insulating material 25 is difficult. If the insulating material 25 is deposited by the chemical vapor deposition (CVD) method, the insulating material 25 uniformly adheres onto the surface of the CNT 31, and thus the deposition of the insulating material 25 in layers only at lower part of the nanomaterial aggregate layer 23 becomes difficult, although the burying ability is good. In addition, because of the atmosphere at the time of CVD film-forming, the CNT 31 is oxidized, nitrified, or damaged by plasma.

According to the embodiment, high burying ability is attained by setting the insulating material 25 to a material of relatively small molecular weight, thus reliably causing the insulating material 25 to reach the lower part of the nanomaterial aggregate layer 23. By setting the insulating material 25 to a material inducing cross-linking reaction by condensation reaction and the like, the adhesion between the insulating material 25 and the CNT 31 can be assured. By setting the insulating material 25 to a material inducing cross-linking reaction by heat treatment in an inert atmosphere, there is not generated damage of CNT accompanied with the heat treatment. By setting the insulating material 25 to a hydrophobic material, in the process shown by the Step S12 in FIG. 3, on wet-washing the pillar 16, discharge of the insulating material 25 carried by the washing liquid can be suppressed. By selecting the insulating material 25 to a material having resistance to ammonia, on forming the side wall shown by the Step S13 in FIG. 3, damage of the insulating material 25 can be prevented during the CVD operation using ammonia gas as the raw material. The insulating material which satisfies the above conditions includes an insulating material (SiOCH) containing silicon (Si), oxygen (O), carbon (C), and hydrogen (H); such as MSQ.

According to the embodiment, the CNT dispersion liquid is coated and dried in the process of the Step S4 shown in FIG. 3, the solution of insulating material is coated and dried in the process of the Step S6, and annealing treatment is applied as shown by the Step S8, and thus the cross-linking between CNTs and the cross-linking between molecules of insulating material 25 are simultaneously performed. Through the processing, the number of heating cycles can be decreased to lower the manufacturing cost of the memory device 1.

Next, a description will be given of a comparative example of the embodiment.

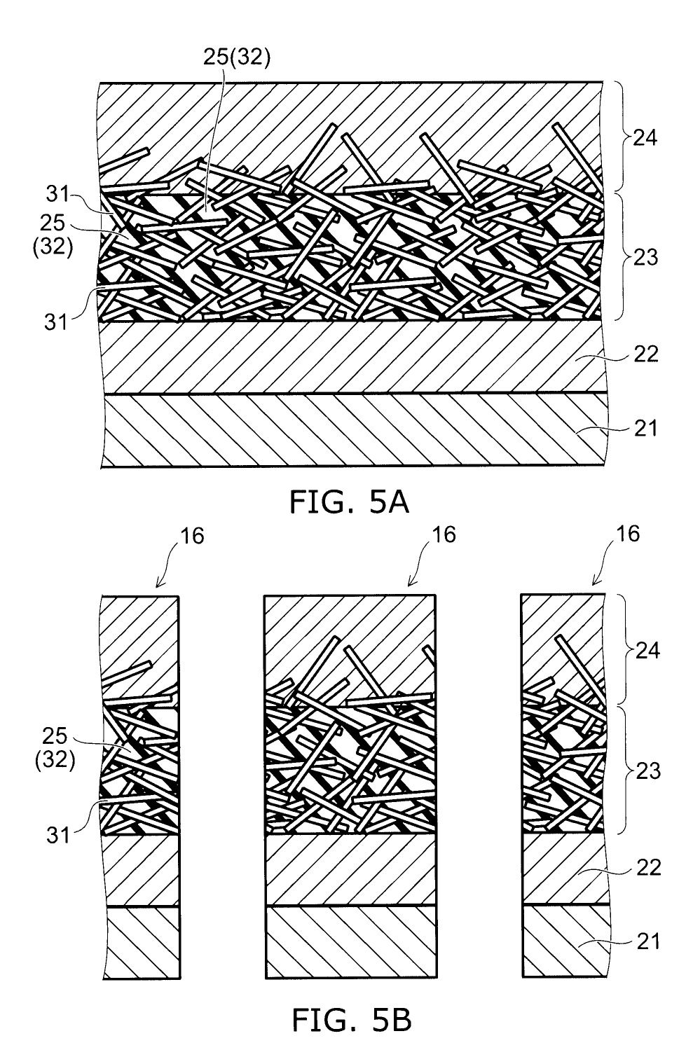

FIG. 6 is a schematic cross-sectional view illustrating a pillar of a memory device according to the comparative example.

As illustrated in FIG. 6, in the memory device according to the comparative example, no insulating material 25 (refer to FIG. 2) is buried in the nanomaterial aggregate layer 23. That type of memory device can be manufactured through the manufacturing method described in the above-described first embodiment by omitting the process shown by the Steps S6 and S7 in FIG. 3.

In the comparative example, since no insulating material 25 (refer to FIG. 2) is located in the gap 32 in the nanomaterial aggregate layer 23, the mechanical strength of the nanomaterial aggregate layer 23 is low. Furthermore, when forming the upper electrode layer 24, since the conductive material enters deeply into the gap 32 of the nanomaterial aggregate layer 23, the flatness of the lower surface of the upper electrode layer 24 becomes poor. Because of this, the flatness of the upper surface of the upper electrode layer 24 also becomes poor. As a result, the characteristics of the memory cell become inhomogeneous. Furthermore, when the conductive material passes through the gap 32 to reach the lower electrode layer 22, the nanomaterial aggregate 23 may cause short circuit.

Moreover, in the comparative example, since no insulating material 25 is buried in the gap 32, in the RIE process for forming the pillar 16, ions for etching pass through the gap 32 of the nanomaterial aggregate layer 23 to reach the lower electrode layer 22, and thus the lower electrode layer 22 is etched non-uniformly. As a result, the shape-stability of the lower electrode layer 22 decreases. When the pillar 16 is treated by wet-washing, the pillar 16 becomes easily fracture and collapse at the nanomaterial aggregate layer 23. Furthermore, when forming the side wall, the material of the side wall enters into the nanomaterial aggregate layer 23. For these reasons, the memory device according to the comparative example has poor reliability.

Next, a description will be given of a test example of the embodiment.

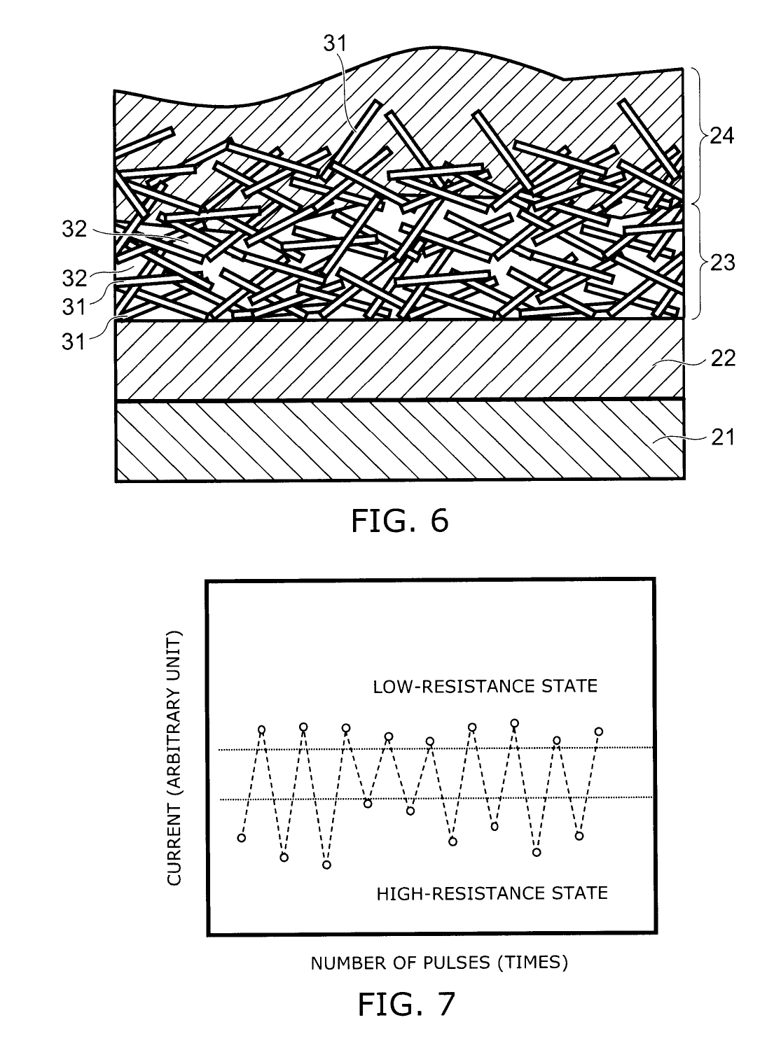

FIG. 7 is a graph illustrating switching characteristics of a memory device according to an example; the horizontal axis represents the number of pulses applied to the pillar, and the vertical axis represents the current flowing through the pillar.

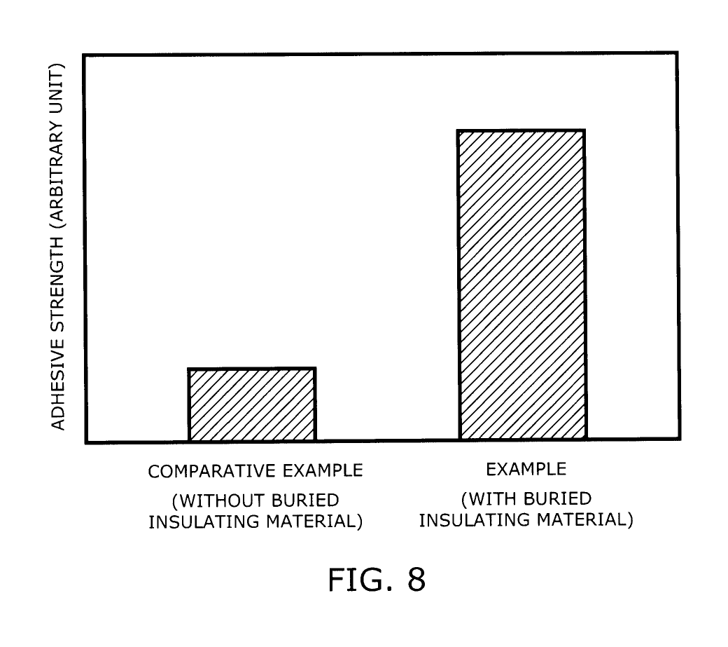

FIG. 8 is a graph illustrating the effect of the insulating material on the adhesive strength of the nanomaterial aggregate layer; the horizontal axis represents the presence/absence of the insulating material, and the vertical axis represents the adhesive strength.

In the test example, the memory device according to the example was manufactured using the method described in the above-described first embodiment. Furthermore, with the method described in the above comparative example, the memory device according to the comparative example was manufactured. As described above, the memory device according to the example has the insulating material 25 (refer to FIG. 2), while the memory device according to the comparative example has no insulating material 25.

As for the memory device according to the example, a pulse voltage was applied to the pillar. As a result, as illustrated in FIG. 7, the setting-action and the resetting-action were repeated in the nanomaterial aggregate layer 23, and thus the “high-resistance state” and the “low-resistance state” are alternately realized. In this way, in the memory device according to the example, the pillar 16 was confirmed to function as the memory cell.

Furthermore, as for the memory devices according to the example and the comparative example, the adhesive strength of the nanomaterial aggregate layer 23 was measured. Specifically, a scratch test was given to the nanomaterial aggregate layer 23. As shown in FIG. 8, the result was that the adhesive strength of the nanomaterial aggregate layer 23 of the memory device according to the example was 1.5 times that of the nanomaterial aggregate layer 23 according to the memory device of the comparative example. The result confirmed the effect of the insulating material 25.

Next, a description will be given of a second embodiment.

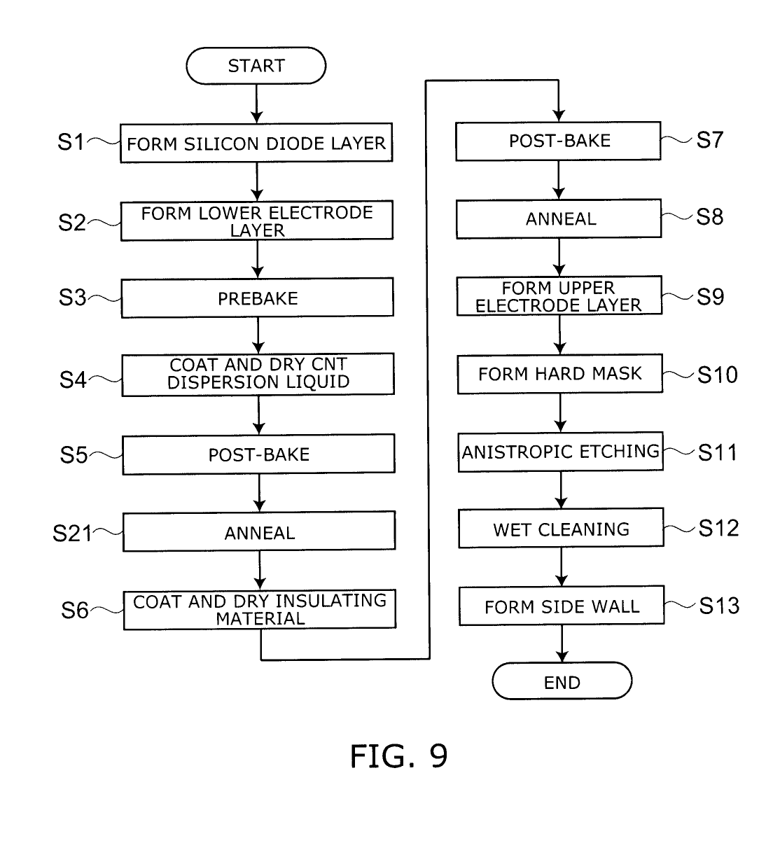

FIG. 9 is a flow chart illustrating a method of forming a pillar, in a method for manufacturing a memory device according to the embodiment.

As illustrated in FIG. 9, compared with the method for manufacturing the memory device according to the above-described first embodiment (refer to FIG. 3), the method for manufacturing the memory device according to the embodiment differs in that annealing process shown by the Step is provided between the post-baking process of the nanomaterial aggregate layer shown by the Step S5 and the coating and drying process of the insulating material shown by the Step S6.

That is, in the embodiment, after the post-baking process shown by the Step S5 in FIG. 9 is completed, the substrate is cooled to room temperature and is taken out from the coater. Then, as shown by the Step 21 in FIG. 9, the substrate is charged into the vertical furnace to perform annealing treatment thereto. The annealing treatment shown in the Step S21 is a heat treatment similar to the annealing treatment shown by the Step S8. For example, in the annealing treatment shown by the Step S21, the atmosphere is a nitrogen atmosphere, the heating temperature is in a range from 500° C. to 600° C., and the heating time is 1 hour. As a result, cross-linking reaction occurs between CNTs 31 and CNTs 31 loosely binds together. After that, the substrate is cooled to room temperature, and is taken out from the vertical furnace. Then, the substrate is again charged into the coater, and the process of the Step S6 and following process are executed. The manufacturing method other than that described above in the embodiment is similar to that in the above-described first embodiment.

According to the embodiment, after the post-baking process shown by the Step S5 in FIG. 9, the annealing treatment shown by the Step S21 is executed to cause the cross-linking reaction between CNTs 31, followed by coating the insulating material as shown by the Step S6. As a result, since there exits no insulating material 25 between CNTs 31 on executing the cross-linking reaction between CNTs 31, the CNTs 31 can be more reliably bound to each other. The effects of the embodiment other than those described above are similar to those of the above-described first embodiment.

Next, a description will be given of a third embodiment.

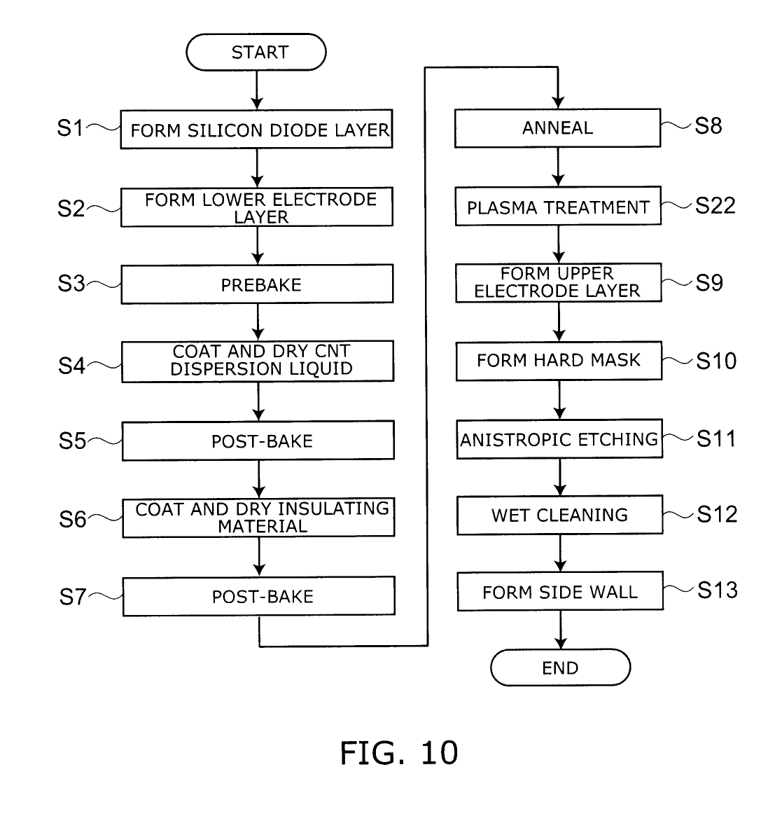

FIG. 10 is a flow chart illustrating a method of forming a pillar, in a method for manufacturing a memory device according to the embodiment.

As illustrated in FIG. 10, in comparison with the method for manufacturing the memory device according to the above-described first embodiment (refer to FIG. 3), the method for manufacturing the memory device according to the embodiment differs in that plasma treatment process shown by the Step 22 is executed between the annealing process shown by the Step S8 and the forming of the upper electrode layer shown by the Step S9.

That is, in the embodiment, after the annealing process shown by the Step S8 in FIG. 10 is completed, the substrate is cooled to room temperature and is taken out from the coater. Then, as shown by the Step 22 in FIG. 10, the substrate is charged into a plasma treatment unit to generate plasma such as a rare gas plasma which has a higher etching speed relative to the insulating material 25 than that relative to the CNT 31, and thus to bring the plasma into contact with the upper surface of the substrate, that is, the upper surface of the nanomaterial aggregate layer 23. As a result, the insulating material 25 adhered to the surface of the portion of CNT 31 protruded from the upper surface of the deposited layer made of the insulating material 25 is removed. After that, the substrate is taken out from the plasma treatment unit and is charged into the PVD unit. Then, the process of the Step S9 and following process are executed. The manufacturing method other than that described above in the embodiment is similar to that in the above-described first embodiment.

According to the embodiment, in the process shown by the Steps of S1 to S8 in FIG. 10, the insulating material 25 is filled in the gap 32, and as shown by the Step S22, the unnecessary insulating material 25 adhered to the CNT 31 is removed using a rare-gas plasma, and then as shown by the Step S9, the upper electrode layer 24 is formed. As a result, the CNT 31 and the upper electrode layer 24 can further be reliably joined together. The effects of the embodiment other than those described above are similar to those of the above-described first embodiment.

Next, a description will be given of a fourth embodiment.

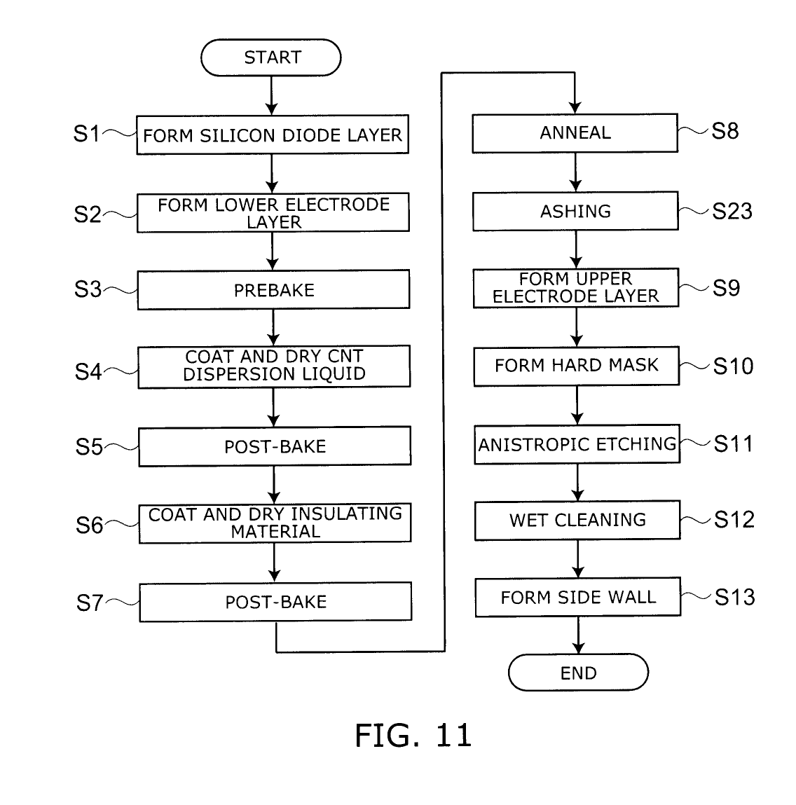

FIG. 11 is a flow chart illustrating a method of forming a pillar, in a method for manufacturing a memory device according to the embodiment.

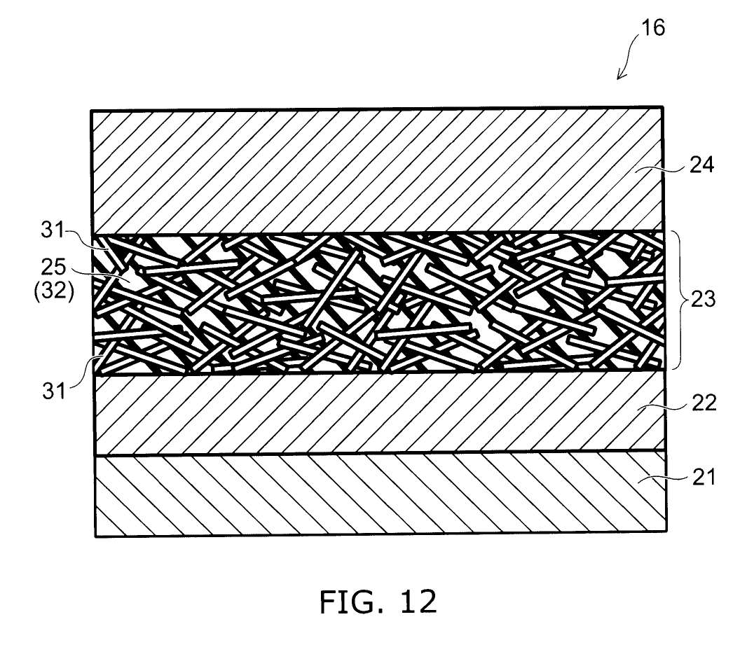

FIG. 12 is a schematic cross-sectional view illustrating the pillar in the memory device according to the embodiment.

As illustrated in FIG. 11, in comparison with the method for manufacturing memory device according to the above-described first embodiment (refer to FIG. 3), the method for manufacturing memory device according to the embodiment differs in that ashing process shown by the Step S23 is provided between the annealing process shown by the Step S8 and forming process of the upper electrode layer shown by the Step S9. As a result, in the memory device according to the embodiment, as illustrated in FIG. 12, the upper surface of the CNT 31 and the upper surface of the insulating material 25 are approximately the same plane, and no CNT 31 is buried in the upper electrode layer 24.

That is, in the embodiment, after the annealing process shown by the Step S8 in FIG. 11 is completed, the substrate is cooled to room temperature and is taken out from the coater. Then, as shown by the Step S23 in FIG. 11, the substrate is charged into the plasma treatment unit to generate a plasma which has a higher etching speed relative to the CNT 31 than that relative to the insulating material 25, such as a mixed plasma of nitrogen and hydrogen (N₂/H₂), a plasma of ammonia (NH₃), or a plasma of oxygen (O₂), and thus to bring the plasma into contact with the substrate. Therefore, the portion of CNT 31 protruded from the upper surface of the deposited layer made of the insulating material 25 is removed by ashing treatment, as illustrated in FIG. 12. As a result, the upper surface of the CNT 31 and the upper surface of the insulating material 25 are approximately the same plane, and the upper surface of the deposited layer made of the insulating material 25 becomes flat. After that, the substrate is taken out from the plasma treatment unit, and is again charged into the coater to execute the Step S9 and following process. The manufacturing method other than that described above in the embodiment is similar to that in the above-described first embodiment.

According to the embodiment, in the process shown by the Step 1 to the Step 8 in FIG. 11, after the gap 32 is filled with the insulating material 25, the plasma treatment is performed to remove the portion of CNT 31 protruded from the deposited layer of the insulating material 25, as shown in the Step 23, followed by forming the upper electrode layer 24 as shown by the Step 9. As a result, the lower surface of the upper electrode layer 24 can be further flat. The effects of the embodiment other than those described above are similar to those of the above-described first embodiment.

Next, a description will be given of a fifth embodiment.

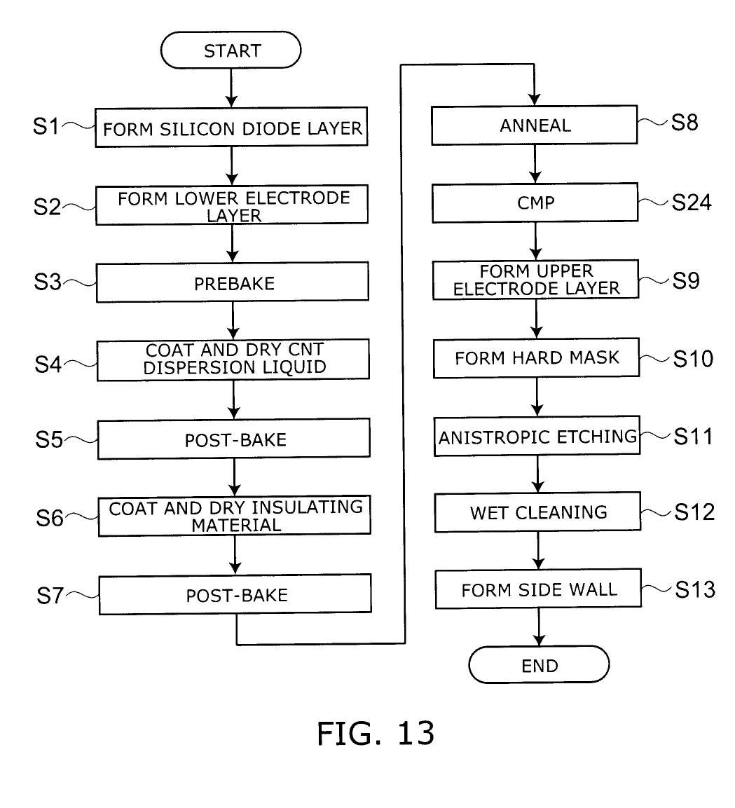

FIG. 13 is a flow chart illustrating a method of forming a pillar, in a method for manufacturing a memory device according to the embodiment.

As illustrated in FIG. 13, in comparison with the method for manufacturing memory device according to the above-described first embodiment (refer to FIG. 3), the method for manufacturing the memory device according to the embodiment differs in that CMP process shown by the Step S24 is provided between the annealing process shown by the Step S8 and the forming process of the upper electrode layer shown by the Step S9. Furthermore, in the memory device according to the embodiment, in the same way as the memory device according to the above-described fourth embodiment (refer to FIG. 12), the upper surface of the CNT 31 and the upper surface of the insulating material 25 are approximately the same plane, and no CNT 31 is buried in the upper electrode layer 24.

That is, in the embodiment, after the annealing process shown by the Step S8 in FIG. 13 is completed and after the substrate is cooled to room temperature, the substrate is taken out from the coater. Then, as shown by the Step S24 in FIG. 13, the substrate is charged into the CMP unit to apply CMP to the upper surface of the substrate. As a result, as illustrated in FIG. 12, the portion of CNT 31 protruded from the upper surface of the deposited layer made of the insulating material 25 is removed. After that, the substrate is taken out from the CMP unit, and is charged into the PVD unit to execute the Step S9 and following process. The manufacturing method other than that described above in the embodiment is similar to that in the above-described first embodiment. Furthermore, the effects of the embodiment are similar to those of the above-described fourth embodiment.

Next, a description will be given of a sixth embodiment.

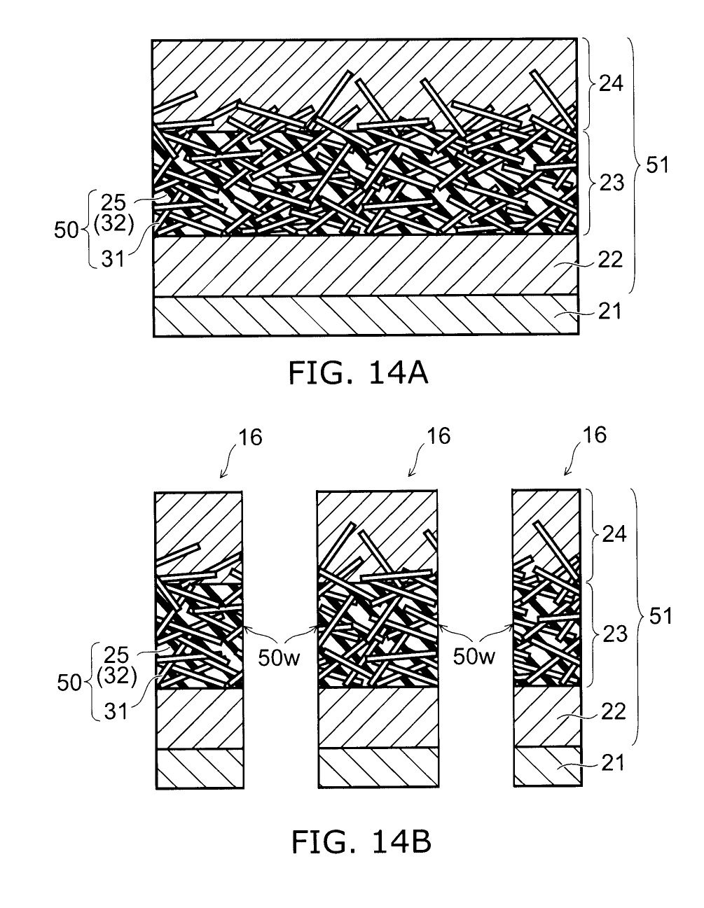

FIGS. 14A and 14B, and FIGS. 15A and 15B are process cross-sectional views illustrating a method for manufacturing a memory device according to the sixth embodiment.

In the sixth embodiment, a state shown in FIG. 5A is preliminarily prepared via a manufacturing process similar to FIG. 4A to FIG. 5A. A state shown in FIG. 14A is the same as a state shown in FIG. 5A.

For example, the substrate described above is charged to a PVD unit to deposit a conductive material such as tungsten and titanium nitride from above the upper part of the nanomaterial aggregate layer 23 using the PVD method. At this time, the conductive material enters into the gap 32 to deposit on the deposited layer made of the insulating material 25, and thus covers the portion of exposed CNT 31. As a result, the upper electrode layer 24 is formed while the CNT 31 is buried in lower part of the upper electrode layer 24.

Here, if a layer having the insulating material 25 filled in the gap 32 of the nanomaterial aggregate layer 23 is taken as a stacked body 50, at this stage the stacked body 50 is formed on the lower electrode layer 22, and the upper electrode layer 24 is formed on the stacked body 50. A layer including the lower electrode layer 22, the stacked body 50 and the upper electrode layer 24 is taken as a stacked body 51.

Subsequently, after the stacked body 51 is formed, a hard mask (not shown) made of, for example, silicon oxide is formed on the upper electrode layer 24. Then, a resist film (not shown) is formed on the hard mask, followed by performing patterning using the lithography to leave the resist film on a domain for forming the pillar 16 (not shown). After that, by using the patterned resist film as the mask, there is performed anisotropic etching such as reactive ion etching (RIE) to perform patterning of the hard mask (not shown).

Next, as shown in FIG. 14B, the patterned hard mask is used as the mask to perform anisotropic etching such as RIE.

By the etching, there are selectively removed the upper electrode layer 24, the nanomaterial aggregate layer 23, the lower electrode layer 22 and the silicon diode layer 21, and thus the pillar 16 is formed. In this way, the stacked body 51 is selectively etched and a side surface 50w of the stacked body 50 is exhibited. An etching gas of the stacked body 51 is a mixed gas of, for example, oxygen (O₂) and fluorocarbon (CFₓ) gas.

Next, as shown in FIG. 15A, an active gas 52 including at least one selected from the group of hydrogen (H) ion, oxygen (O) ion, hydrogen (H) radical and oxygen (O) radical is exposed to the side surface 50w of the stacked body 50. Thereby, the nanomaterial aggregate layer 23 is selectively etched from the side surface 50w of the stacked body 50. Alternatively, a defect occurs in the nanomaterial aggregate layer 23 itself. This state is shown in FIG. 15B.

As shown in FIG. 15B, the side surface of the nanomaterial aggregate layer 23 is partially removed to retreat from the side surface 50w of the stacked body 50 toward the center of the pillar 16. An insulating material having the nanomaterial aggregate layer 23 removed, namely, an insulating layer 55 is formed in a portion where the nanomaterial aggregate layer 23 is retreated.

A thickness of the insulating layer 55 in a direction normal to a direction from the lower electrode layer 24 toward the upper electrode layer 25 is adjusted by etching time of a part of the nanamaterial aggregate layer 23. That is, the thickness of the insulating layer 55 increases with this etching time. It is preferable to select hydrogen (H) radical or oxygen (O) radical enabling more isotropic etching of the nanomaterial aggregate layer 23 as a gas for etching the part of the nanomaterial aggregate layer 23.

In this way, in the sixth embodiment, after selectively etching the stacked body 51 and exhibiting the side surface 50w of the stacked body 50, the part of the nanomaterial aggregate layer 23 is selectively etched from the side surface 50w. Gas species for selectively etching the stacked body 51 are different from gas species for selectively etching the nanomaterial aggregate layer 23.

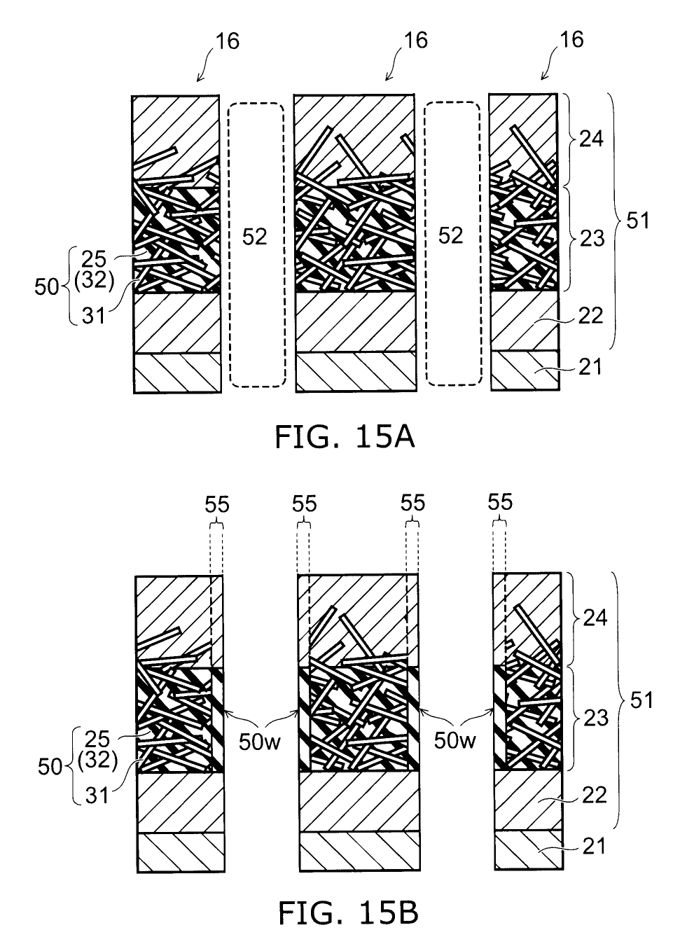

FIGS. 16A and 16B are process views illustrating the method for manufacturing the memory device according to the sixth embodiment, FIG. 16A illustrates an upper process view and FIG. 16B illustrates a cross-sectional process view.

After the nanomaterial aggregate layer 23 is etched, a protecting layer 56 is formed on the side surface of the pillar 16. A material of the protecting layer 56 is, for example, silicon nitride (Si₃N₄). Formation of the protecting layer 56 makes it hard for moisture to penetrate into the pillar 16 from outside the pillar 16.

In this way, a memory device 2 according to the sixth embodiment includes the nanomaterial aggregate layer 23 of a plurality of fine conductors aggregating via the gaps 32 and the insulating material 25 disposed in the gaps 32. Furthermore, the memory device 2 includes the lower electrode layer 22 contacting the lower surface of the nanomaterial aggregate layer 23, the upper electrode layer 24 contacting the upper surface of the nanomaterial aggregate layer 23 and the insulating layer 55 covering the side surface of the nanomaterial aggregate layer 23.

As viewed in a direction normal to the upper surface of the nanomaterial aggregate layer 23, a side surface 23w of the nanaomaterial aggregate layer 23 is located at a position near to a center of the nanomaterial aggregate layer 23 with respect to a side surface 22w of the lower electrode layer 22 or a side surface 24w of the upper electrode layer 24. In other words, a region where the nanomaterial aggregate layer 23 exists is located inside a region where the insulating material 25 exists.

For example, an area of the region where the nanomaterial aggregate layer 23 exists is not more than 90% of an area of the region where the insulating material 25 exists. Each of the plurality of fine conductors is a carbon nanotube. The insulating material 25 includes at least silicon, oxygen, carbon and hydrogen, and is hydrophobic.

A width of the nanomaterial aggregate layer 23 in each pillar 16 in the memory device 2 is narrower than a width in the memory device 1. Here “width” is a width in a direction generally parallel to the upper surface of the nanomaterial aggregate layer 23.

Thereby, the memory device 2 has a smaller operating current than the memory device 1. For example, when the area of the region where the nanomaterial aggregate layer 23 exists is 50% to the area of the region where the insulating material 25 exists, comparing with the case where the area of the region where the nanomaterial aggregate layer 23 exists is 100% to the area of the region where the insulating material 25 exists, in the case where a current path being in electrical continuity between the upper electrode layer 24 and the lower electrode layer 22 reduces to ½, the operating current reduces to generally ½. Moreover, “low resistance state” and “high resistance state” can be achieved at a lower voltage compared with the memory device 1. That is, these effects make the low power consumption operation possible.

The insulating layer 55 covers around the nanomaterial aggregate layer 23. That is, the memory device 2 has a structure of the nanomaterial aggregate layer 23 disposed in the tubular insulating layer 55. In other words, the nanomaterial aggregate layer 23 is supported by the insulating layer 55 provided on the outer periphery. This makes it possible to maintain an approximately same level of a mechanical strength of the nanomaterial aggregate layer 23 compared with the level in the memory device 1. The insulating material 25 is an SOG (Spin On Glass) layer formed by using the spin-coating method. Therefore, the adhesiveness between the insulating material 25 (insulating layer 55) and the lower electrode layer 22 and the adhesiveness between the insulating material 25 (insulating layer 55) and the upper electrode layer 24 are good. This suppresses collapse of the pillar 16 at a portion of the nanomaterial aggregate layer 23 and subsidiary fracture of the pillar 16 considering the nanomaterial aggregate layer 23 as a fracture surface.

The insulating layer 55 is a layer having the CNT 31 removed from the insulating material 25. Therefore, a lot of holes of a few nanometers exist in the insulating layer 55. Namely, in the memory device 2, a parasitic capacitance around the nenaomaterial aggregate layer 23 is low compared with the memory device 1.

The treatment of selectively etching the stacked body 51 to exhibit the side surface 50w of the structure body 50 and the treatment of selectively etching the part of the nanomaterial aggregate layer 23 from the side surface 50w can be performed by only switching gas species in the same etching apparatus. Therefore, the sixth embodiment does not cause an increase of manufacturing cost.

Here, in the case where the process is conducted without removal of the part of the nanomaterial aggregate layer 23, for example, the following trouble occurs.

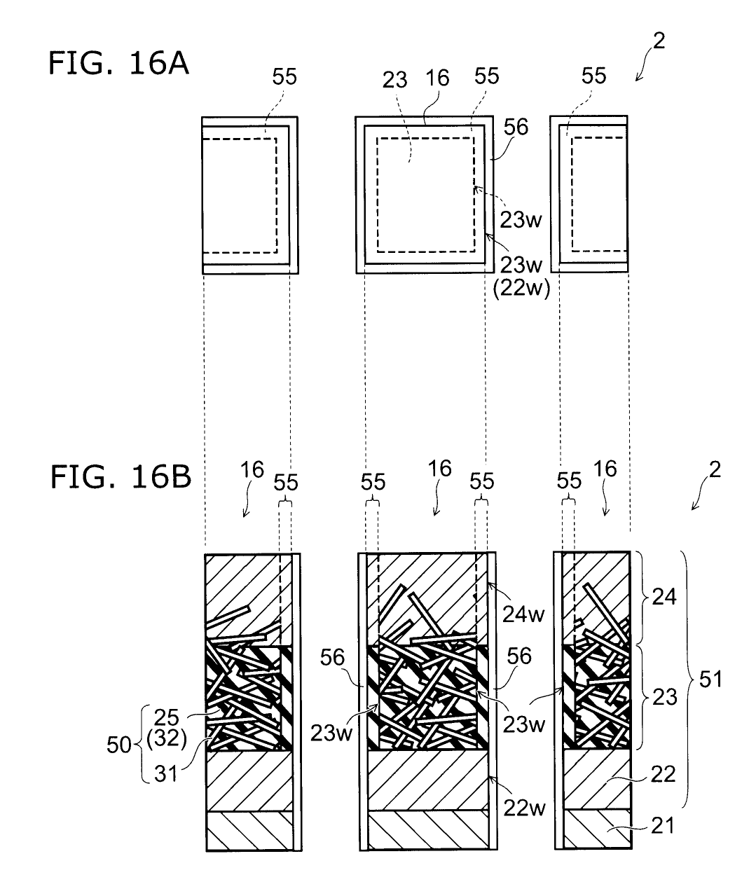

FIGS. 17A and 17B are cross-sectional process views illustrating a method for manufacturing a memory device according to a comparative example.

As shown in FIG. 17A, it is assumed that a residue 60 adheres to the side wall of the structure body 50 after forming the pillar 16. If the residue 60 is conductive, as shown in FIG. 17B, the electrical continuity between the lower electrode layer 22 and the upper electrode layer 24 is always caused via the CNT 31 and the residue 60.

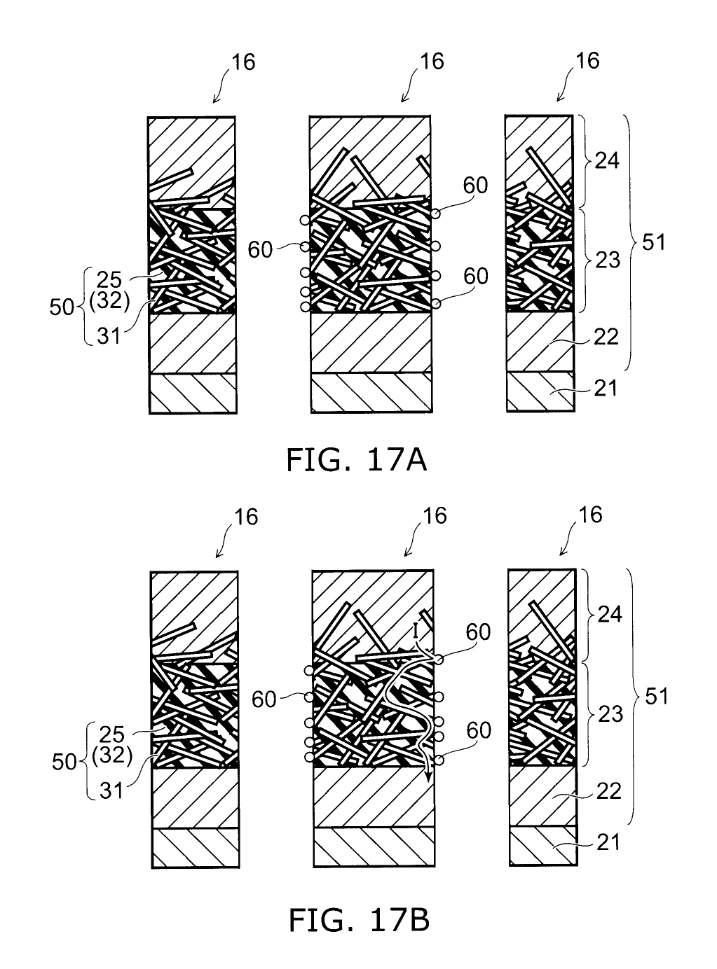

FIG. 18 is a cross-sectional process view illustrating the method for manufacturing the memory device according to the sixth embodiment.

On the contrary, the sixth embodiment has an advantage shown below. For example, even if the residue 60 adheres to the side wall of the structure body 50 after forming the pillar 16, the insulating layer 55 is already formed between the nanomaterial aggregate layer 23 and the residue 60. Therefore, the short circuit does not occur between the lower electrode layer 22 and the upper electrode layer 24 via the CNT 31 and the residue 60.

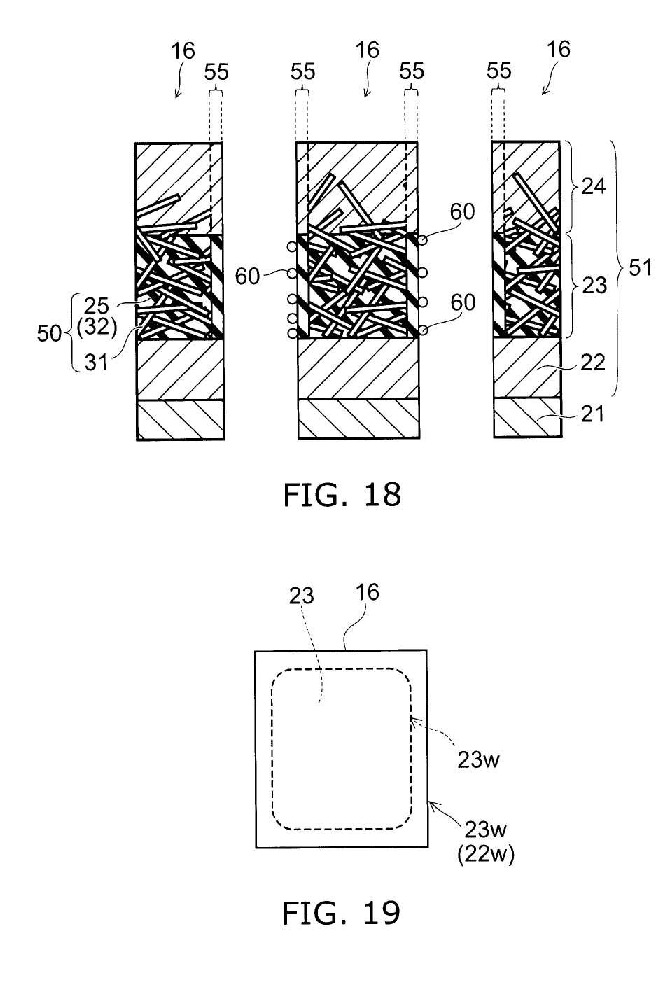

FIG. 19 is an upper schematic view illustrating a variation of the memory device according to the sixth embodiment.

After removing the part of the nanomaterial aggregate layer 23, morphology is not limited to the morphology shown in FIG. 16A, but may be the morphology shown in FIG. 19. For example, as viewed in the direction normal to the upper surface of the nanomaterial aggregate layer 23, the nanomaterial aggregate layer 23 is not necessary to be rectangular, and the corner may have a structure of a curved surface.

In the embodiment, the pillar may be overlapped in a plurality. Thereby, a memory device with a higher recording density is formed.

Next, a description will be given of a seventh embodiment.

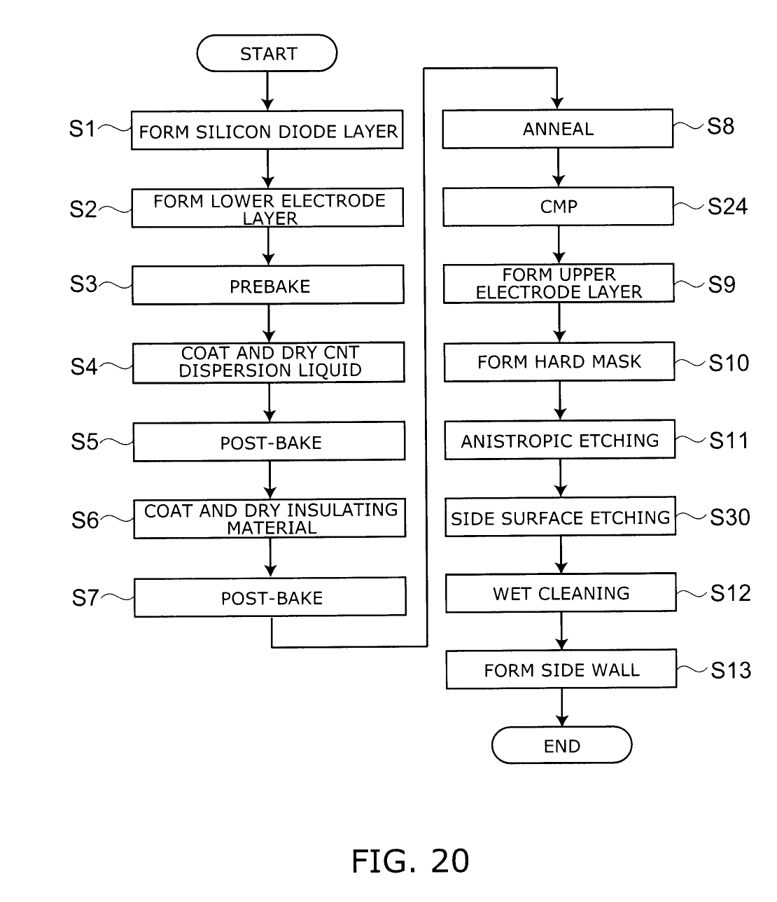

FIG. 20 is a flow chart illustrating a method of forming pillar in a method for manufacturing a memory device according to the seventh embodiment.

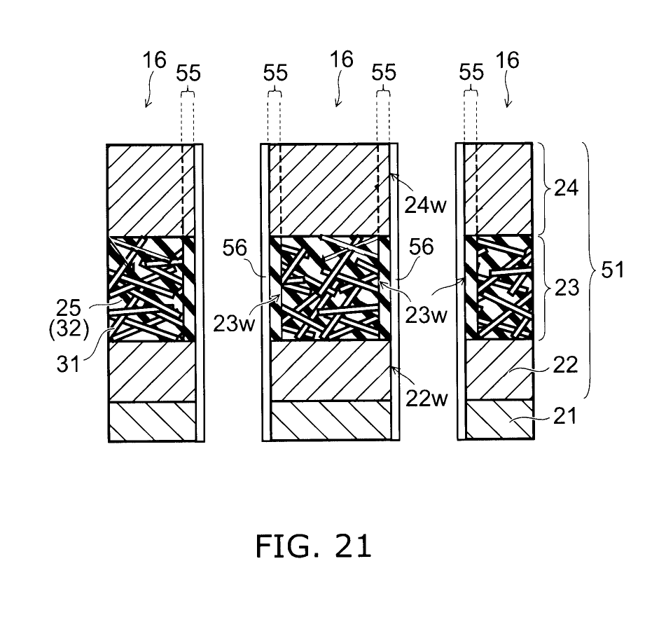

FIG. 21 is a schematic cross-sectional view illustrating the pillar of the memory device according to the seventh embodiment.

As shown in FIG. 20, Step S1 to Step S11 of the method for manufacturing the memory device according to the embodiment are the same as the method for manufacturing the memory device according to the fifth embodiment previously described (see FIG. 13).

In the embodiment, after anisotropic etching according to Step S11, as shown in FIG. 15A, etching of the side surface of the nanomaterial aggregate layer 23 is performed (Step S30). After this, wet cleaning (Step S12) is performed and then the side wall (protecting layer 56) is formed (Step S13).

In the memory device according to the embodiment, as with the memory device according to the fifth embodiment previously described, the upper surface of the CNT 31 and the upper surface of the insulating material 25 form the generally same plane, and the CNT 31 is not buried in the upper electrode layer 24.

Thereby, as shown in FIG. 21, a structure is formed, in which a portion protruding from the upper surface of the deposited layer made of the insulating material 25 in the CNT 31 is removed.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

For example, the insulating material 25 may be buried in the gap 32 so as to substantially prevent void from being formed therein, or may have a porous structure containing voids having a size similar to the size of the CNT 31 or smaller than the size of the CNT 31. In the case of porous structure, the voids may be formed in the entire nanomaterial aggregate layer 23, may be formed only in the lower part thereof, or may be formed only in the central part in the thickness direction thereof.

The above-described embodiments describe the examples in which, in the nanomaterial aggregate layer 23, there exists no CNT 31 which contacts with both the lower electrode layer 22 and the upper electrode layer 24. However, there may exist a very small number of CNTs 31 which penetrate the nanomaterial aggregate layer 23 in the thickness direction and which contact with both the lower electrode layer 22 and the upper electrode layer 23. Even in that case, there can be given a difference in the resistivity of nanomaterial aggregate layer 23 between that in a “low-resistance state” and that in a “high-resistance state”, which thus allows the nanomaterial aggregate layer 23 to function as the memory layer.

Furthermore, the above-described embodiments can be executed in combination therebetween. For example, as in the second embodiment, the annealing treatment of the CNT 31 and the annealing treatment of the insulating material 25 may be executed in a separate process from each other, and as in the third embodiment, the plasma treatment with rare gas may be executed to thereby remove the insulating material 25 adhered to the CNT 31.

According to the above-described embodiments, a memory device having high reliability and a method for manufacturing thereof can be realized.

What is claimed is:

1. A memory device comprising:
a nanomaterial aggregate layer of a plurality of fine conductors aggregating via gaps; and
an insulating material disposed in the gaps.

2. The device according to claim 1, wherein
the fine conductors are carbon nanotubes, and
an extending direction of the carbon nanotubes is closer to a direction parallel to a lower surface of the nanomaterial aggregate layer than a direction normal to the lower surface.

3. The device according to claim 1, wherein the insulating material is filled in the gaps by coating method.

4. The device according to claim 1, further comprising:
a lower electrode layer contacting with a lower surface of the nanomaterial aggregate layer; and
an upper electrode layer contacting with an upper surface of the nanomaterial aggregate layer,
the fine conductors contacting with both the lower electrode layer and the upper electrode layer do not exist.

5. The device according to claim 1, wherein the insulating material contains silicon, oxygen, carbon, and hydrogen, and is a hydrophobic material.

6. The device according to claim 1, wherein the insulating material is methylsilsesquioxane.

7. The device according to claim 1, further comprising:
a word line interconnect layer including a plurality of word lines extending in a first direction; and
a bit line interconnect layer including a plurality of bit lines extending in a second direction intersecting with the first direction,
the word line interconnect layer and the bit line interconnect layer being stacked alternately each other, and the nanomaterial aggregate layer being a part of a pillar disposed between each of the word lines and each of the bit lines.

8. A memory device comprising:
a nanomaterial aggregate layer of a plurality of fine conductors aggregating via gaps;
an insulating material disposed in the gaps;
a lower electrode layer contacting a lower surface of the nanomaterial aggregate layer;
an upper electrode layer contacting an upper surface of the nanomaterial aggregate layer; and
an insulating layer covering a side surface of the nanomaterial aggregate layer,
as viewed in a direction normal to the upper surface of the nanomaterial aggregate layer, the side surface of the nanomaterial aggregate layer being located at a position near to a center of the nanomaterial aggregate layer with respect to a side surface of the lower electrode layer or a side surface of the upper electrode layer.

9. The device according to claim 8, wherein each of the plurality of fine conductors is a carbon nanotube.

10. The device according to claim 8, wherein the insulating layer includes at least silicon, oxygen, carbon and hydrogen, and is hydrophobic.

11. The device according to claim 9, wherein an extending direction of the carbon nanotube is closer to a direction parallel to the lower surface of the nanomaterial aggregate layer than a direction normal to the lower surface.

12. The device according to claim 8, wherein the insulating material is filled in the gaps by a coating method.

13. The device according to claim 8, wherein
the fine conductors contacting both the lower electrode layer and the upper electrode layer do not exist.

14. The device according to claim 8, wherein the insulating material is methylsilsesquioxane.

15. The device according to claim 8, further comprising:
a word line interconnect layer including a plurality of word lines extending in a first direction; and
a bit line interconnect layer including a plurality of bit lines extending in a second direction intersecting with the first direction,
the word line interconnect layer and the bit line interconnect layer being stacked alternately each other, and the nanomaterial aggregate layer being a part of a pillar disposed between each of the word lines and each of the bit lines.

16. A method for manufacturing a memory device, the method comprising:
forming a nanomaterial aggregate layer of a plurality of fine conductors aggregating via gaps between the fine conductors; and
filling the gaps with an insulating material.

17. The method according to claim 16, wherein the filling the insulating material includes coating the insulating material.

18. The method according to claim 16, further comprising:
heating the nanomaterial aggregate layer and the filled insulating material.

19. The method according to claim 16, further comprising:
heating the nanomaterial aggregate layer; and
heating the filled insulating material,
heating the nanomaterial aggregate layer being executed before the filling the insulating material.

20. The method according to claim 16, further comprising:
bringing plasma having a higher etching rate with respect to the insulating material than an etching rate with respect to the fine conductors into contact with an upper surface of the nanomaterial aggregate layer; and
forming an upper electrode layer by depositing a conductive material on a deposited layer made of the insulating material.

21. The method according to claim 16, further comprising:
bringing plasma having a higher etching rate with respect to the fine conductors than an etching rate with respect to the insulating material into contact with an upper surface of the nanomaterial aggregate layer; and
forming an upper electrode layer by depositing a conductive material on a deposited layer made of the insulating material.

22. The method according to claim 16, further comprising:
removing a portion of the fine conductors protruding from an upper surface of a deposited layer made of the insulating material by polishing an upper surface of the nanomaterial aggregate layer; and
forming an upper electrode layer by depositing a conductive material on the deposited layer.

23. The method according to claim 16, wherein the fine conductors is carbon nanotubes.

24. The method according to claim 16, further comprising:
forming a word line interconnect layer including a plurality of word lines extending in a first direction;
forming a bit line interconnect layer including a plurality of bit lines extending in a second direction intersecting with the first direction; and
forming a pillar by selectively removing the nanomaterial aggregate layer filled with the insulating material,
the forming the word line interconnect layer and the forming the bit line interconnect layer are executed alternately each other, and the forming the nanomaterial aggregate layer, the filling the insulating material, and the forming the pillar are executed between the forming the word line interconnect layer and the forming the bit line interconnect layer.

25. The method according to claim 16, wherein a part of the nanomaterial aggregate layer is selectively etched from a side surface of a structure body having the insulating material filled in the gaps of the nanomaterial aggregate layer after the filling the gaps with the insulating material.

26. The method according to claim 16, wherein the insulating material includes at least silicon, oxygen, carbon and hydrogen.

27. The method according to claim 25, wherein the part of the nanomaterial aggregate layer is selectively etched from the side surface of the structure body using a gas including at least one selected from the group of hydrogen ion, oxygen ion, hydrogen radical and oxygen radical.

28. The method according to claim 25, wherein after forming the structure body on a lower electrode layer, forming an upper electrode layer on the structure body, and forming a stacked body including the lower electrode layer, the structure body and the upper electrode layer, the stacked body is selectively etched to exhibit the side surface of the structure body and the part of the nanomaterial aggregate layer is selectively etched from the side surface.

29. The method according to claim 28, wherein gas species for selectively etching the stacked body are different from gas species for selectively etching the part of the nanomaterial aggregate layer.
